(19) United States
(12) Patent Application Publication
(10) Pub. No.: US 2023/0307559 A1
(43) Pub. Date: Sep. 28, 2023

(54) A SOLAR CELL STRUCTURE AND A METHOD OF FORMING A SOLAR CELL STRUCTURE

(71) Applicant: NewSouth Innovations Pty Limited, Sydney, New South Wales (AU)

(72) Inventors: Brett Jason HALLAM, Sydney, New South Wales (AU); Catherine Emily CHAN, Sydney, New South Wales (AU); Arman MAHBOUBI SOUFIANI, Sydney, New South Wales (AU); Yuchao ZHANG, Sydney, New South Wales (AU)

(21) Appl. No.: 18/020,844

(22) PCT Filed: Oct. 29, 2021
(86) PCT No.: PCT/AU2021/051268

§ 371 Date: Feb. 10, 2023

(30) Foreign Application Priority Data
Oct. 29, 2020 (AU) 2020903934

(51) Int. Cl. H01L 31/0224; H01L 31/18

(52) U.S. Cl. CPC H01L 31/022441; H01L 31/1888

(57) ABSTRACT

A solar cell structure (10) comprises a semiconductor material having a first doped region (12) and at least one second doped region (26) of the same polarity as that of the first region (12). The solar cell structure (10) further comprises at least one dielectric layer (20) at the surface of the first region (12), and a conductive portion (18) located over the at least one second region (26) to form an electrical contact with the at least one second region (26). The at least one second region (26) traverses the conductive portion (18) at least three times such that at least three electrical contacts (32) are formed between the at least one second region (26) and the conductive portion (18).

### CROSS-REFERENCE TO RELATED APPLICATIONS

This application claims the benefit of priority of Australian Provisional Patent Application Number 2020903934, filed on 29 Oct. 2020, which is incorporated by reference herein, in its entirety.

### TECHNICAL FIELD

The present invention relates to a solar cell structure and a method of forming a solar cell structure.

### BACKGROUND

Since the 1970s, research and development into improving solar cell performance has resulted in significant increases in solar cell efficiencies. The most efficient solar cells are however not necessarily the most commercially feasible for production at an industrial level at affordable costs to the consumer, and more recently attention has turned to producing highly efficient solar cells that are commercially viable.

Screen-printed Passivated rear emitter contact (PERC) solar cells and Tunnel Oxide Passivated Contact (TOPCon) solar cells are among the latest considered to be highly efficient industrial solar cells, achieving efficiencies above 23%, with PERC cells currently being the dominant technology. Other commercially available solar cells that are cheaper and easier to manufacture include conventional solar cells formed with screen-printed metallic contacts or “fingers”, despite commonly having lower efficiencies of around 20% due to a full area rear metal contact being formed using screen printing technology.

In conventional solar cells with screen-printed metallic contacts, an emitter region of the silicon substrate underneath metallic contacts is usually heavily-doped to reduce the contact resistance between the silicon and metallic contacts. Moreover, since there is a limit to how narrow the metallic contacts can be formed by screen printing, the heavy doping also assists in overcoming lateral conductivity issues due to the need for the metallic contacts to be spaced apart by a sufficient degree to reduce shading losses. However, it is generally desirable to limit the amount of doping in the emitter region and the width of the metallic contacts to reduce recombination rates at a surface and/or interface, which are known to reduce the efficiency of the solar cell.

A technique that has been developed to reduce the amount of heavy doping in the emitter region is forming laser-doped selective-emitters (LDSE), where highly-doped “selective-emitter” regions are formed by laser doping only at locations substantially underneath the metallic contacts, with a remainder of the emitter region being lightly doped. This improves contact resistance and reduces recombination at the metal/silicon interface while reducing overall doping in the emitter region between the metal fingers. In the current preferred industrial approach, laser doping is performed directly after phosphorus emitter diffusion using the residual phosphosilicate glass (PSG) layer as the dopant source. Subsequently, screen-printed metal contacts are aligned to the laser doped regions after dielectric deposition, with the metallisation firing process enabling the metal to penetrate through the dielectric layer to contact the underlying heavily-doped silicon. However, efficiencies in such solar cells are also limited by the need for the highly-doped regions to be wide enough to accommodate for the width of the metallic contacts plus an amount of tolerance to enable adequate yield and throughput in mass production due to difficulties in aligning the metallic contacts with respective highly-doped regions, particularly when screen-printing. For example, current attempts to incorporate LDSE in mass-manufactured PERC solar cells use wide (100-150 micrometres) laser-doped bands or lines (see FIG. 1) with aligned screen-printed metallic contacts. This results in about a 10% laser-doped area and about 3-5% metal-silicon interface areas. The high metal silicon interface area and laser-doped areas undesirably increases the dark saturation current density (J₀) of the device, limiting open-circuit voltages (V_{OC}) of the solar cell to 680-690 mV and therefore limits its power conversion efficiency.

In at least one embodiment, the present invention may provide a solar cell structure that potentially addresses one or more of the above issues.

Any discussion of documents, acts, materials, devices, articles or the like which has been included in the present specification is not to be taken as an admission that any or all of these matters form part of the prior art base or were common general knowledge in the field relevant to the present disclosure as it existed before the priority date of each of the appended claims.

### SUMMARY OF DISCLOSURE

According to a first aspect, there is provided solar cell structure comprising:
a semiconductor material having a first doped region and at least one second doped region of the same polarity as that of the first region, the at least one second region located at a surface portion of the semiconductor material and in electrical contact with the first region, the at least one second region having a doping profile different to that of the first region;
at least one dielectric layer at the surface of the first region, wherein portions of the at least one dielectric layer are removed and the at least one second region is formed at the portions at which the at least one dielectric layer is removed; and
a conductive portion located over the at least one second region to form an electrical contact with the at least one second region;
wherein the at least one second region traverses the conductive portion at least three times such that at least three electrical contacts are formed between the at least one second region and the conductive portion.

In one specific embodiment the dielectric layer is removed by laser doping and the at least one second region is formed by the laser doping at the portions at which the dielectric layer is removed. The at least one second region may be formed by applying a dopant on the first region and directing a laser over the applied dopant to form the at least one second region and remove the dielectric material.

The at least one second region may extend along, and within the bounds of, a notional band defined by spaced-apart side boundary lines that are substantially parallel with a longitudinal axis of the conductive portion, wherein a width of the notional band is greater than a width of the conductive portion.

Each second region may be continuous, for example, each second region may be continuous from one end of the conductive portion to another end of the conductive portion.

The at least one second region may traverse the conductive portion between 2 and 20 times per millimetre measured along a longitudinal axis of the conductive portion.

The at least one second region may traverse the conductive portion between 5 and 10 times per millimetre measured along a longitudinal axis of the conductive portion.

A total surface area of the conductive portion overlapping the at least one second region may be less than 2% of a total area of the surface of the solar cell structure on which the conductive portion is located.

A width of the at least one second region may be: between 10 μm and 50 μm; or approximately 20 μm.

The width of the notional band may be less than approximately 150 μm.

The width of the conductive portion may be: less than 2 mm, or less than 1 mm, or less than 500 μm, or less than 100 μm, or less than 50 μm, or between 20 μm and 40 μm, or approximately 30 μm.

A form of the at least one second region may approximate a wave shape.

The conductive portion may comprise a metallic material and is applied by screen printing.

The semiconductor material may be silicon. The applied dopant source may comprise aluminium oxide. The aluminium oxide may also passivate the surface of the first region. The at least one second region may be doped with boron or aluminium, or a combination of boron and aluminium.

The applied dopant source may contain phosphorus. The at least one second region may be doped with phosphorus.

The at least one second region may have a doping concentration higher than that of the first region.

The conductive portion may be in the form of a distinct metal finger and one or more of the at least one second region only traverses the metal finger along a length of the finger.

According to a second aspect, there is provided a method of forming a solar cell structure, the method comprising:
providing a substrate of semiconductor material, the substrate having a first doped region of a first doping concentration;
forming at least one second region in the substrate such that the at least one second region is located at a surface portion of the semiconductor material and in electrical contact with the first region, wherein the at least one second region has a doping profile different to that of the first region; and
forming a conductive portion over the at least one second region such that the at least one second region traverses the conductive portion at least three times, wherein electrical contacts are established between the conductive portion and the at least one second region at locations where the at least one second region traverses the conductive portion.

The forming the conductive portion may comprise screen-printing the conductive portion over the at least one second region.

The forming the at least one second region may comprise using laser doping and applying a dopant source on the first region and directing a laser over the applied dopant source in the form of the at least one second region.

Before the at least one second region is formed, the method may comprise depositing a passivation layer over the first region.

After forming the at least one second region using laser doping and locally removing the passivation layer using the laser, the method may comprise screen-printing the conductive layer over the at least one second region. The method may further comprise firing at least some portions of the conductive portion to establish the electrical contacts.

The semiconductor material may further comprise at least one dielectric layer at a surface of the substrate, the method comprising:
removing portions of the at least one dielectric layer to form one or more exposed regions in the at least one dielectric layer such that the substrate is exposed at the exposed regions; and
forming a conductive portion over at least a portion of the one or more exposed regions such that the exposed regions traverse the conductive portion at least twice.

The at least one second region may have a doping concentration higher than that of the first region.

The method may further comprise growing a thin passivation layer over the exposed regions. The thin passivation layer may comprise a native oxide or polysilicon layer.

According to a third aspect, there is provided a method of forming a solar cell structure, the method comprising:
providing a solar cell structure comprising:
   a substrate of a semiconductor material, the substrate having a first doping concentration; and
   a dielectric layer at a surface of the substrate;
removing portions of the dielectric layer to form one or more exposed regions in the dielectric layer such that an underlaying layer in the solar cell structure is exposed at the exposed regions; and
applying a conductive portion over at least a portion of the one or more exposed regions such that the exposed regions traverse the conductive portion at least twice.

The one or more exposed regions may form: a series of parallel lines; or a continuous line; or semi-continuous line approximating a wave.

The method may comprise applying the conductive portion by screen-printing.

The method may comprise depositing passivating contact layer at least over the one or more exposed regions after removal of the portions of the dielectric layer and before applying the conductive portion.

The solar cell structure may comprise a passivated contact layer underneath the dielectric layer.

The method may comprise using a laser to locally remove the portions of the dielectric layer and expose a portion of the passivated contact layer.

According to a fourth aspect, there is provided a solar cell structure comprising:
a substrate of a semiconductor material, the substrate having a doping concentration;
at least one dielectric layer at a surface of the substrate, wherein portions of the dielectric layer are removed to form one or more exposed regions in the dielectric layer such that an underlying layer in the solar cell structure is exposed at the exposed regions; and
a conductive portion over at least a portion of the one or more exposed regions such that the exposed regions traverse the conductive portion at least twice.

A passivated contact layer may be deposited underneath the dielectric layer. The passivated contact layer may comprise at least one of: polysilicon; conductive oxide; conductive oxide that are less than 200 nm thick.

The substrate may comprise at least one first doped region of a first doping concentration and dielectric or passivation layer profile and at least one second doped region located at a surface portion of the semiconductor material and in electrical contact with the first region, wherein the at least one second region has a dielectric or passivation layer profile different to that of the first region.

The at least one second region may extend along, and within the bounds of, a notional band defined by spaced-apart side boundary lines that are substantially parallel with a longitudinal axis of the conductive portion, wherein a width of the notional band is greater than a width of the conductive portion.

Each second region may be continuous.

The at least one second region may traverse the conductive portion between 2 and 20 times per millimetre measured along a longitudinal axis of the conductive portion.

The at least one second region may traverse the conductive portion between 5 and 10 times per millimetre measured along a longitudinal axis of the conductive portion.

A total surface area of the conductive portion overlapping the at least one second region may be less than 2% of a total area of the surface of the solar cell structure on which the conductive portion is located.

A width of the at least one second region may be: between 10 μm and 50 μm; or approximately 20 μm.

The width of the notional band may be less than approximately 150 μm.

The width of the conductive portion may be: less than 2 mm, or less than 1 mm, or less than 500 μm, or less than 100 μm, or less than 50 μm, or between 20 μm and 40 μm, or approximately 30 μm.

A form of the at least one second region may approximate a wave shape.

The conductive portion may comprise a metallic material and is applied by screen printing.

The semiconductor material may be silicon.

The conductive portion may be in the form of a distinct metal finger and one or more of the at least one second region only traverses the metal finger along a length of the finger.

The dielectric layer may comprise at least one of: polysilicon; conductive oxide;

conductive oxide that is less than 200 nm thick.

### BRIEF DESCRIPTION OF DRAWINGS

Embodiments of the disclosed solar cell structures and methods will now be described by way of example only with reference to the accompanying drawings in which:

FIG. 1 is a schematic plan view of a portion of a known solar cell structure;

FIG. 2 is a sectional view of the solar cell structure shown in FIG. 1 across cut C1;

FIG. 3 is a schematic plan view of a solar cell structure according to an embodiment disclosed herein;

FIG. 4A is a sectional view of the solar cell structure shown in FIG. 3 across cut C2;

FIG. 4B is a sectional view of the solar cell structure shown in FIG. 3 across cut C3;

FIG. 4C is a sectional view of the solar cell structure shown in FIG. 3 across cut C4;

FIG. 5 is another schematic plan view of the solar cell structure shown in FIG. 3;

FIGS. 6A-6D show a series of plots of simulation results obtained for solar cells with various parameters;

FIG. 7 is a plot of simulation results obtained for a solar cell structure according to an embodiment disclosed herein;

FIG. 8 is a schematic plan view of a solar cell structure according to another embodiment disclosed herein;

FIG. 9 is a flow diagram of a method for forming a solar cell structure according to an embodiment disclosed herein; and

FIG. 10 is a flow diagram of a method for forming a solar cell structure according to another embodiment disclosed herein.

### DETAILED DESCRIPTION OF SPECIFIC EMBODIMENTS

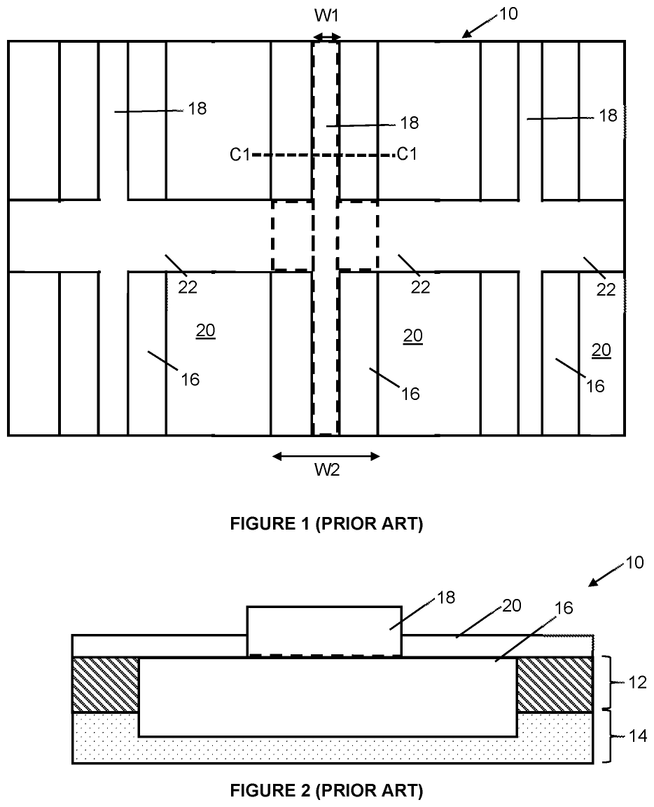

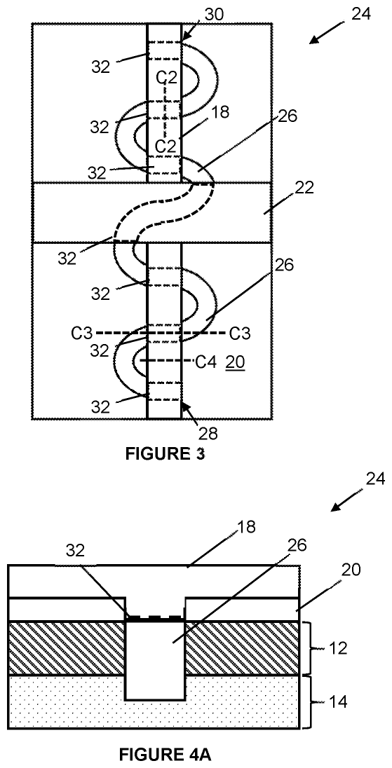

FIGS. 1 and 2 show portions of a conventional solar cell structure 10 with screen-printed metallic contacts or “fingers” 18 and highly-doped n₊ selective-emitter regions 16. The solar cell structure 10 comprises a silicon substrate as the semiconductor material having an n-type emitter region 12 and a p-type base region 14 typical of a PERC solar cell. Those skilled in the art will appreciate that in alternative examples other semiconductor materials can be used and the emitter region 12 could be p-type and the base region 14 could be n-type. For example, the solar cell structure may be a n-PERT or TOPCon solar cell with a boron-emitter diffusion for the p-type contact.

FIG. 2 shows one of the plurality of highly-doped n₊ selective-emitter regions 16 being formed within the emitter region 12, which in this example is a laser-doped selective-emitter (LDSE) region 16 located at a surface portion of the semiconductor material. Conductive contact portions, which in this example are in the form of metallic “fingers” 18, are aligned with a respective LDSE region 16. Although only one metal finger 18 and associated LDSE region 16 is shown in FIG. 2 for convenience, it will be understood that a typical solar cell of the type described comprises multiple metal fingers 18 and LDSE regions 16 spaced-apart side-by-side, generally as indicated in FIG. 1.

As shown in FIG. 2, the metal finger 18 makes direct contact to the LDSE region 16. A remainder of the emitter region 12 is lightly doped with the same polarity as the LDSE region 16. The solar cell structure 10 in this example also includes a dielectric layer or stack of dielectric layers 20 above the emitter region 12 and screen-printed busbars 22 in electrical contact with the metal fingers 18 for transferring the direct current collected by the metal fingers 12 to a solar inverter. The screen-printed fingers 18 and busbars 22 may be formed in different screen-printing processes with different pastes to ensure that the busbar does not penetrate dielectric layer 20 to make contact to emitter region 12 (e.g., a floating busbar). However, it will be appreciated by a skilled person in the art that a single printing process could be performed with a single fire-through paste where LDSE regions 16 are also formed underneath the busbar regions and the busbar also makes direct contact with the LDSE region.

In this example of the conventional solar cell structure 10, the LDSE region 16 is substantially in the form of a linear strip or band having a width W2 of between 100-150 μm and the metal (e.g. Ag) finger 18 has a width W1 between 30-45 μm (in this example approximately 37 μm) with a spacing of approximately 1-1.5 mm between adjacent metal fingers. The LDSE region 16 is wider than the metal finger 18 to allow for alignment tolerance when screen-printing the metal finger 18 over the respective LDSE region 16. This results in about 10% of the area of the total area of the surface of the solar cell on which the metal finger 18 is located as attributable to the LDSE region and about 3-5% of that area attributable to the metal-silicon interface areas, which at least in PERC solar cells for example is believed to limit open-circuit voltages (V_{OC}) to 680-690 mV and therefore its power conversion efficiency. Specifically, the amount of excess LDSE region 18 which does not form part of the metal-silicon contact areas is believed to contribute to limiting the V_{OC} (due to the high dark saturation current density, J₀, of the LDSE areas) and short-circuit current J_{SC} (due to reduced current collection in the LDSE areas), thus affecting solar cell performance.

One way of improving the efficiency of a solar cell having the structure 10 is to reduce the width of the LDSE regions. However, this would increase the difficulty of aligning the screen-printed metal fingers 18 with respective LDSE regions 16 in mass production while maintaining high throughput and high yield. For example, in an ideal case which should result in the highest possible efficiency by current standards, a thin strip of screen-printed metal finger would be aligned with a thin LDSE region with an alignment precision of ±10-15 μm; however, this poses challenges for printing thousands of wafers per hour using the same screen as the screen stretches during standard use during the life of the screen when performing more than 10,000 prints.

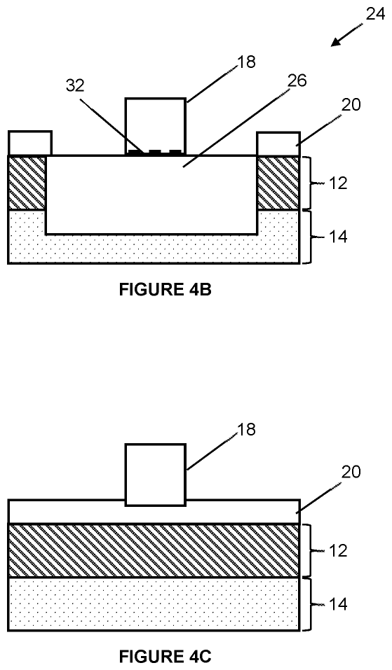

FIGS. 3 to 5 show an embodiment of a presently disclosed solar cell structure 24. The same reference numerals will be used for components of the structure 24 that are effectively the same as corresponding components of FIGS. 1 and 2. Like the solar cell structure 10 shown in FIG. 1, the structure 24 in this example comprises a silicon substrate as the semiconductor material with an n-type emitter region 12 and a p-type base region 14. The structure 24 also comprises metal fingers 18 (one of which is shown in FIG. 3), a dielectric layer 20 above the emitter region 12 and screen-printed busbars 22 in electrical contact with the metal fingers 18. Like the structure 10, the emitter region 12 of the structure 24 comprises first and second differently doped regions of the same polarity: highly-doped LDSE regions 26 formed generally underneath respective metal fingers 18 at a surface portion of the semiconductor material, and lightly-doped regions elsewhere in the emitter region 12.

However, unlike the LDSE region 16 of FIGS. 1 and 2, the LDSE region 26 in the structure 24 is non-linear and crosses (traverses) the metal finger 18 multiple times. Described another way, the LDSE region 26 has a first end 28 and a second end 30 and traverses the metal finger 18 at least twice between the first end 28 and second end 30. As a result, discrete electrical contacts at respective interfaces 32 between the metal finger 18 and LDSE region 26 are formed only where portions of the LDSE region 26 are directly beneath the metal finger 18. In general, the number of discrete electrical contacts 32 formed for one metal finger 18 corresponds to the number of times the LDSE region 26 crosses underneath the metal finger 18.

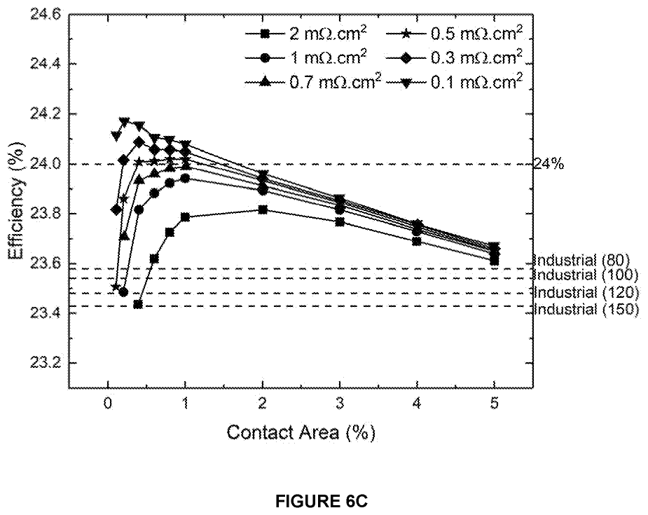

In this embodiment, LDSE region 26 has a continuous wave-like form approximating the shape of a sine wave (see particularly FIGS. 3 and 5), though other formations are possible. In other words, the LDSE region 26 has a periodic pattern. The LDSE region 26 traverses the metal finger 18 at least 3 times and may traverse the metal finger 18 up to 20 times per millimetre measured along a longitudinal axis L of the metal finger 18 (see FIG. 5), for example. Preferably, the LDSE region 26 traverses the metal finger 18 between 2 and 10 times per millimetre measured along the longitudinal axis L. According to a specific non-limiting example: a width of the metal finger 18 may be between 30 μm and 45 μm (e.g. approximately 37 μm); a width W3 of the LDSE region 26 may be between 15 μm and 25 μm (e.g. approximately 20 μm); and the LDSE region 26 may have a “wavelength” L2 of between approximately 200 μm and 500 μm, or in other words, the LDSE region 26 may cross the metal finger 18 approximately every 100 μm to 250 μm.

Furthermore, the wave-like form of the LDSE region 26 extends beyond the metal finger 18 to allow tolerance for misalignment when screen-printing the metal finger 18 onto the LDSE region 26. Thus, with reference to FIG. 5, if the LDSE region 26 is considered to fit within a notional band B, where the band B is defined by minimally spaced-apart side boundary lines B1 and B2 substantially parallel with the longitudinal axis L of the metal finger 18, a width W4 of the notional band is greater than a width W1 of the metal finger 18. In a specific example, the width W4 of the notional band may be between 50-150 μm, e.g. approximately 100 μm, i.e. the same or similar as the width W2 of the LDSE region 16 of the solar cell structure 10 to provide the same alignment tolerance as for the structure 10. In other examples, the width W4 of the notional band may be in a range out of 50-150 μm, including widths below 50 μm and widths up to 300 μm or 500 μm. It will be appreciated that in practice, the width W4 may differ accordingly to suit other parameters of a particular design within the scope of the invention, such as improved alignment tolerances.

Therefore, according to embodiments of the invention such as the example of the structure 24 described above, the same or a similar alignment tolerance can be achieved (since W4≈W2) with a much smaller total contact area at the interface 32 compared to the convention solar cell structure 10. For instance, in the example described above, the surface area of the LDSE region 26 is reduced to <1.5% of the total area of the corresponding surface of the solar cell 24 (compared to approximately 8.6% for LDSE region 16 of the solar cell 10). Furthermore, the total area of the metal-silicon interfaces 32 is reduced to approximately 0.5% of the total area of the corresponding surface of the solar cell 24 (compared to approximately 4.5% for solar cell 10).

It will thus be appreciated that the wave-like form of the LDSE region 26 allows for the surface area of the LDSE region 26 to be reduced without sacrificing alignment tolerance. In doing so, a significant reduction in the recombination rates at the emitter-metal interface 32 may be achieved, which has been identified as performance-limiting for at least some solar cells such as but not limited to PERC and TOPCon solar cells. It may also reduce the front dark saturation current density, which also negatively impacts the efficiency of a solar cell.

Additionally, the continuous wave-like and/or semi-continuous form of the LDSE region 16 may be advantageous during the manufacturing process since processing equipment need not be stopped and started (compared to for instance a series of discrete formations), thus potentially adding to processing efficiency.

To illustrate, Tables 1 and 2 below show simulated efficiency rates for a PERC solar cell with industrial screen-printed metal fingers and LDSE regions in the form of a linear strip or band (as in FIG. 1), where the contact resistivity ρ_{c} of the metal-silicon interface is 2 mΩ·cm² (Table 1) and 1 mΩ·cm² (Table 2).

TABLE 1
(ρ_{c} = 2 mΩ · cm²)

| | Finger | | | |
|---|---|---|---|---|
| LDSE | 50 μm | 40 μm | 30 μm | 20 μm |
| 150 μm | 23.20% | 23.43% | 23.62% | 23.80% |
| 120 μm | 23.28% | 23.48% | 23.69% | 23.88% |
| 100 μm | 23.32% | 23.54% | 23.75% | 23.93% |
| 80 μm | 23.37% | 23.58% | 23.79% | 23.98% |

TABLE 2
(ρ_{c} = 1 mΩ · cm²)

| | Finger | | | |
|---|---|---|---|---|
| LDSE | 50 μm | 40 μm | 30 μm | 20 μm |
| 150 μm | 23.24% | 23.46% | 23.67% | 23.88% |
| 120 μm | 23.31% | 23.52% | 23.74% | 23.94% |
| 100 μm | 23.35% | 23.58% | 23.80% | 24.00% |
| 80 μm | 23.40% | 23.62% | 23.84% | 24.06% |

It can be seen from Tables 1 and 2 above that:
reducing the width of the metal fingers increases the efficiency of the solar cell;
reducing the width of the LDSE region also generally increases efficiency;
generally, higher efficiencies are observed with a lower contact resistivity, ρ_{c}.

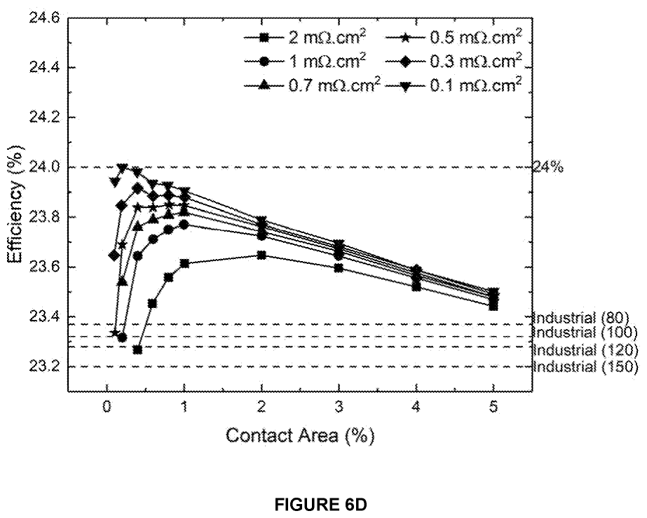

Furthermore, FIGS. 6A-6D each show a graph of simulation results of the performance of an industrial PERC solar cell with differently sized metal fingers (20 μm, 30 μm, 40 μm, 50 μm respectively), the simulations for each metal finger including plots with different contact resistivities ρ_{c} (0.1 mΩ·cm²-2 mΩ·cm²). It can be observed that in all situations, efficiency peaks early with a relatively low contact area percentage of <1%, and then generally declines linearly as contact area increases beyond 1%. However, it should be noted that while the simulation results showed 20 μm-wide metal fingers as resulting in the highest efficiency, achieving such widths using current industrially prevalent screen-printing methods is impractical.

Recent attempts to incorporate LDSE in industrial PERC solar utilise relatively wide LDSE strips (100-150 μm) aligned with screen-printed metal contacts, as in FIG. 1. However, it could be inferred from Tables 1 and 2 above as well as FIGS. 6A-6D (see in particular FIG. 6B, the graph of simulation results for 30 μm-wide metal fingers) that improved efficiencies, for example greater than 24%, could potentially be achieved with current industrial manufacturing practices with:
a lower contact resistivity, preferably 1 mΩ·cm² or less;
thinner metal fingers, e.g. approximately 30 μm wide; and/or
a lower contact area for the LDSE area.

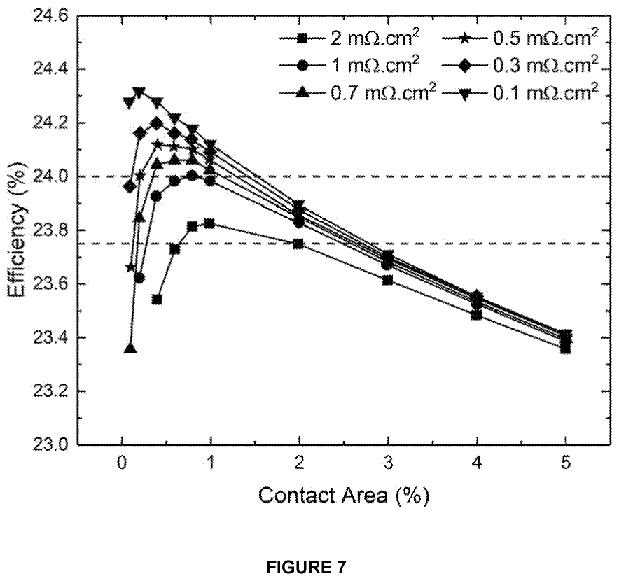

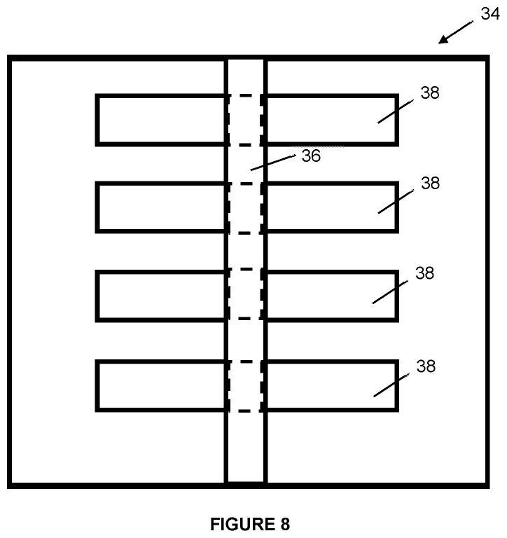

As described above, the lower contact area for the LDSE area could be achieved without sacrificing alignment tolerance by utilising embodiments of the invention such those implementing the wave-like form of the LDSE region 26 shown in FIGS. 3 and 5. To demonstrate, FIG. 7 shows a simulation of the performance of an industrial PERC solar cell 34 with a screen-printed metal finger 36 and 80 μm-wide LDSE region in the form of dashes 38 shown in FIG. 8, the results of which are expected to be similar to that of an LDSE region 26 with a wave-like form. With industrially feasible parameters of 1 mΩ·cm² contact resistivity, a 30 μm-wide metal finger 36 and an 80 μm-wide LDSE region 38, it can be seen that an efficiency above 24% may be attained where the metal-silicon contact area is between 0.5% and 1%, which may be provided by the dashed and/or wave-like form of the LDSE region 38 and 26.

Therefore, in addition to improved efficiency, a further advantage of the solar cell structure 24 described above is that the increased efficiency can potentially be achieved without significant variation or addition from existing manufacturing processes. Accordingly, any additional cost of manufacturing the solar cell structure 24 with higher efficiency (compared to the solar cell structure 10) would be minimal.

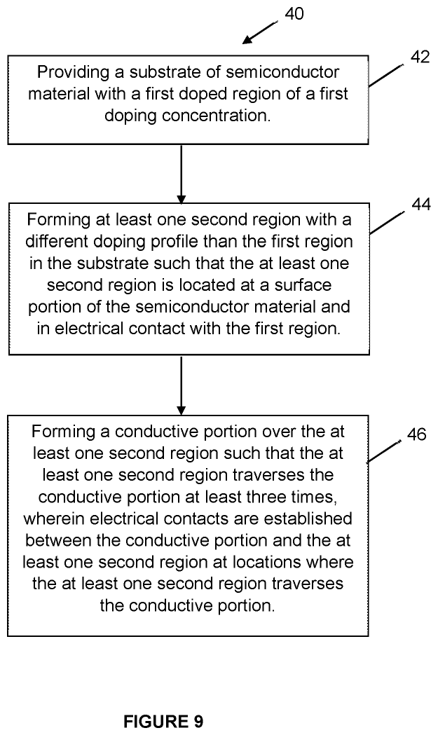

In that regard, with reference to FIG. 9, a method 40 of forming the solar cell structure will be described below according to an embodiment. The solar cell structure formed in this embodiment is for a PERC LDSE solar cell incorporating the structure 24 with screen-printed metal fingers described above with reference to FIGS. 3 to 5. However, it will be appreciated that embodiments of the disclosed method 40 may be applied to other types of solar cells.

The method comprises providing 42 a substrate of semiconductor material, the substrate having a first doped region of a first doping concentration. In this embodiment, the first doped region is the n-doped emitter region 12 (excluding the LDSE region 26) overlying a p-doped base region 14. As will be understood by those skilled in the art, usual processing steps such as but not limited to texturing, diffusion, phosphorous silicate glass (PSG) removal and rear etch etc., may be performed to prepare the semiconductor substrate.

The method further comprises forming 44 a second region in the substrate of a second doping concentration higher than the first doping concentration such that the second region is located at a surface portion of the semiconductor material and in electrical contact with the first region. The second region may have an elongate non-linear form between two ends; or in other words may form an unenclosed non-linear shape. In this embodiment, the second region is the LDSE region 26 having a shape that approximates a sine-wave or other wave-like formation between the first end 28 and the second end 30.

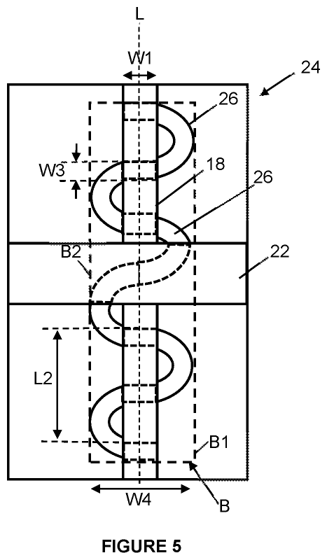

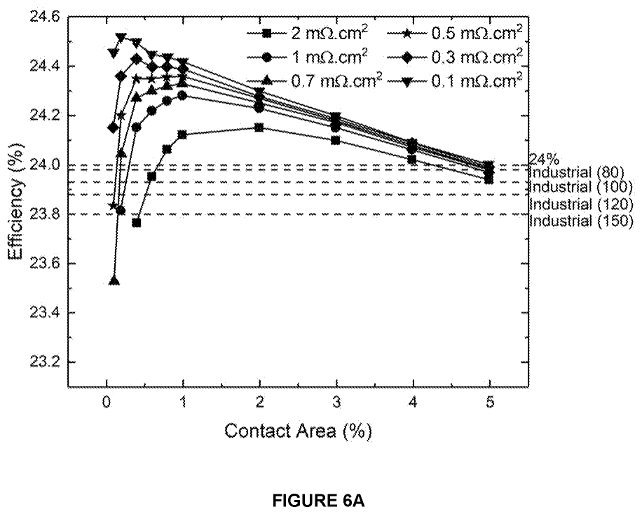

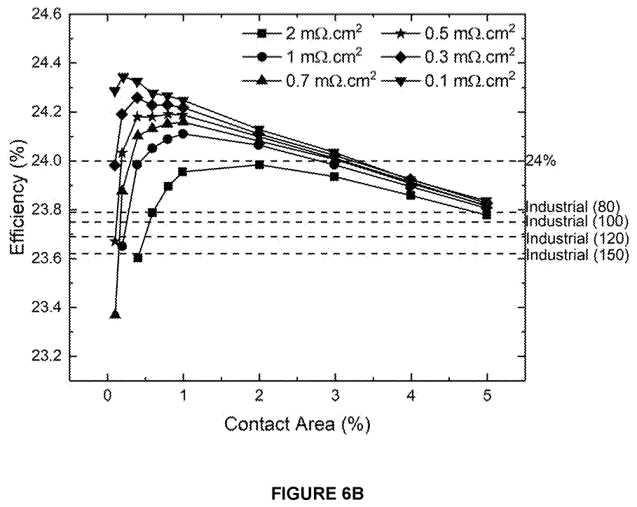

Before forming the LDSE region 26 a dielectric material may be deposited as a surface passivation layer 20. Then, the LDSE region 26 may be formed by applying a dopant source such as phosphoric acid sprayed on top of the passivation layer and directing a laser onto the passivation layer to form the wave-like formation through the passivation layer, resulting in a laser-doped region 26 inset into the emitter region 12 (see FIG. 4A). The laser in this example may be directed such that the wave-like formation is created generally along a notional axis substantially midway between the side boundary lines B1 and B2 (see FIG. 5). The dopant source may then be removed by rinsing.

The method further comprises forming 46 a conductive portion, in this embodiment the metal finger 18, over the LDSE (second) region 26, such that the LDSE region 26 traverses the conductive portion at least two or three times between the first end 28 and second end 30. In this embodiment, the metal finger 18 is formed utilising screen-printing methods well-known to those skilled in the art. The screen-printing method itself therefore will not be described in detail. As described above with reference to FIGS. 3 to 5, the LDSE region 26 may have a periodic form, e.g. a wave-like form that traverses the metal finger 18 at least 3 times, or otherwise between 2 and 20 times (inclusive) per linear millimetre (measured along a longitudinal axis L of the metal finger 18). Preferably, the LDSE region 26 traverses the metal finger 18 between 5 and 10 times per linear millimetre. The width of the metal FIG. 18 and notional band spanning the LDSE region may also be as described above with reference to FIGS. 3 to 5.

Specifically, the metal finger 18 in this embodiment is applied by screen-printing a metallic paste (e.g. silver) onto the LDSE region 26 in a manner that substantially aligns with the LDSE region 26, i.e. aligning with the notional axis along which the LDSE region 26 is formed. Once the metallic paste is printed, it can be seen that the LDSE region 26 traverses it at multiple discrete locations. Then, discrete electrical contacts 32 are established between the conductive portion and the LDSE region 26 at locations where the LDSE region 26 traverses the metal finger 18. As would be understood by those skilled in the art, this can be done by firing or co-firing in a furnace to form the contacts. A non-fire through paste may be used to ensure that the metal-silicon contact is only made at the intersection of the metal finger and LDSE regions.

Similar benefits may be realised by adapting the methods and techniques described above for selective emitters developed for industrial p-type contact of n-type passivated emitter rear totally diffused (n-PERT) or TOPCon solar cells. For instance, the processes followed for a n-PERT or TOPCon solar cell may be similar to the embodiments of the method 40 described above using a PERC solar cell as an example, with few variations such as those described below.

In one example, n-PERT and TOPCon solar cell structures typically comprise a passivation layer (e.g. AlOx) on top of a p⁺ doped (e.g. boron-doped) emitter region at the front side of the cell. The AlOx passivation layer could be used as the dopant source such that no additional dopant source would be required. Accordingly, to form an LDSE region 26 in the n-PERT or TOPCon solar cell, a variation of the embodiment of the method 40 described above for a PERC solar cell could be followed minus the application of a phosphoric acid dopant source and subsequent rinsing. Instead, laser doping is performed after the passivation layer is deposited, using the passivation layer as the dopant source.

The example above for n-PERT and TOPCon solar cells may avoid costly and energy-intensive boron diffusion process that would otherwise be required to form a selective emitter structure. Further, it is envisioned that such techniques could also be implemented on the rear surface of bi-facial PERC solar cells that include an AlOx passivation layer, to form localised back surface field regions.

Optionally, for both PERC and TOPCon solar cells, additional techniques could be implemented to further improve solar cell performance. For example, a further step of growing or depositing a thin, conductive passivation layer over the second region before screen printing could be done to reduce the recombination current density (J₀) at the interface between the second region and the conductive portion, as well as passivate the surface of any exposed laser-doped region. Alternatively, a thin native oxide layer could be grown during firing to partially passivate the exposed laser-doped region.

Also disclosed is a method 48 of forming a solar cell structure in which, in general terms, a wave-like form, series of parallel dashes or lines which may be periodic, or other configuration(s) of one or more doped regions may be formed by removing portions of an existing dielectric layer to expose portions of an underlying doped region or underlying passivation layer (for example a carrier-selective transport layer, eg. doped poly-silicon). Subsequently, a conductive portion such as a metal finger may then be applied over the one or more exposed doped or underlying conductive passivation layer regions to form contacts. Therefore, instead of applying a dielectric layer (e.g. as the surface passivation layer) and forming a laser-doped region through the dielectric as in the embodiment of the method 40 described above, exposed regions are formed by removing portions an existing dielectric layer. Embodiments of the method 48 may be particularly useful for solar cells that are provided with dielectrics and/or passivated contacts already in place, such as TOPCon or other passivated contact solar cells.

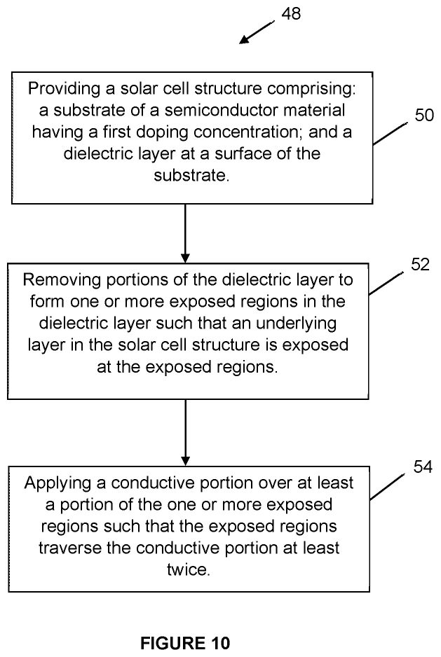

With reference to FIG. 10, an embodiment of the method 48 comprises providing 50 a solar cell structure comprising: a substrate of a semiconductor material, the substrate having a first doping concentration; and a dielectric layer at a surface of the substrate. The dielectric layer may be a capping dielectric layer (e.g. SiN) at the rear of a TOPCon solar cell, which typically covers a passivated contact layer (e.g. doped polysilicon).

The method 48 may further comprise removing 52 portions of the dielectric layer to form one or more exposed regions in the dielectric layer such that the substrate, and therefore an underlying doped region (or underlying passivation layer, for example a carrier-selective transport layer, eg. doped poly-silicon) is exposed where the portions of the dielectric layer have been removed. The portions of the dielectric layer may be removed by laser ablation. It is noted that laser ablation is expected to cause negligible change of dopant profile in the laser processed region. In one example, the laser ablation is conducted to form a series of parallel lines similar to the dashes 38 shown in FIG. 8. However, it will be appreciated that any other shape, pattern or configuration in the dielectric layer is possible, such as but not limited to the wave-like form of the LDSE region 26 shown in FIGS. 3 and 5.

At this stage, if the solar cell structure does not already have a passivating contact layer, one may be applied (e.g. polysilicon or transparent conductive oxides (TCO)) over the laser processed region or over the whole surface of the solar cell.

The method 48 may further comprise applying 54 a conductive portion over at least a portion of the pattern of exposed regions such that the exposed regions traverse the conductive portion at least twice or at least three times. The conductive portion in one example may be a screen-printed metal finger, as described above in relation to embodiments of the method 40 or shown in FIG. 8. In particular, the screen-printed metal finger may be formed by first printing a metal paste (e.g. silver) in alignment over the series of parallel lines. The metal finger in this example would be superimposed in a cross-wise orientation over the series of lines, like the metal finger 36 shown on top of the dashes 38 in FIG. 8. Firing is then conducted to establish electrical contacts at locations where the metal fingers traverse the lines.

It will be appreciated that the length of each line in the series extends beyond the width of the metal finger to allow for alignment tolerance. It will also be appreciated that forming the series of parallel lines or other pattern, configuration etc., provides a doped region that, once aligned with a metal finger, reduces the silicon-metal interface area compared to a continuous linear strip of having a width greater than the metal finger. Similar benefits to the LDSE region 26 described above may thus be realised according to embodiments of the alternative method 48.

It will be understood to persons skilled in the art of the invention that many modifications may be made without departing from the spirit and scope of the invention.

For example, although embodiments of the invention described above are compatible with screen-printed metallised fingers, the invention is not limited thereto, and the metal fingers may be formed by techniques other than screen-printing such as stencil printing.

As another example, embodiments of the invention are not limited to the LDSE regions 26 described with reference to FIGS. 3 to 5, or the series of parallel lines formed by laser ablation described with reference to the method 48. It will be understood that other shapes, configurations and patterns are possible that also serve to reduce the LDSE area and/or emitter-metal interface area to improve solar cell efficiency. For example, the LDSE region 26 may have a wave-like form that is not continuous but is instead segmented, or a series of two or more broken lines. As another example, the LDSE region may have any other periodic formation, such as but not limited to a zig-zag or square wave.

In the claims which follow and in the preceding description of the invention, except where the context requires otherwise due to express language or necessary implication, the word “comprise” or variations such as “comprises” or “comprising” is used in an inclusive sense, i.e. to specify the presence of the stated features but not to preclude the presence or addition of further features in various embodiments of the invention.

1-27. (canceled)

28. A method of forming a solar cell structure, the method comprising:
providing a solar cell structure comprising:
a substrate of a semiconductor material, the substrate having a first doping concentration; and
a dielectric layer at a surface of the substrate;
removing portions of the dielectric layer to form one or more exposed regions in the dielectric layer such that an underlying layer in the solar cell structure is exposed at the exposed regions; and
applying a conductive portion over at least a portion of the one or more exposed regions such that the exposed regions traverse the conductive portion at least twice.

29. The method of claim 28, wherein the one or more exposed regions form: a series of parallel lines; or a semi-continuous line approximating a wave.

30. The method of claim 28, comprising applying the conductive portion by screen-printing.

31. The method of claim 28, comprising depositing a passivating contact layer at least over the one or more exposed regions after removal of the portions of the dielectric layer and before applying the conductive portion.

32. The method of claim 28, wherein the solar cell structure comprises a passivated contact layer underneath the dielectric layer.

33. The method of claim 32, further comprising using a laser to locally remove the portions of the dielectric layer and expose a portion of the passivated contact layer.

34. A solar cell structure comprising:
a substrate of a semiconductor material, the substrate having a doping concentration;
at least one dielectric layer at a surface of the substrate, wherein portions of the dielectric layer are removed to form one or more exposed regions in the dielectric layer such that an underlying layer in the solar cell structure is exposed at the exposed regions; and
a conductive portion over at least a portion of the one or more exposed regions such that the exposed regions traverse the conductive portion at least twice.

35. The solar cell structure of claim 34, wherein a passivated contact layer is deposited underneath the dielectric layer.

36. The solar cell structure of claim 34, wherein the substrate comprises a passivation layer and wherein the portions of the dielectric layer are removed to form the one or more exposed regions in the dielectric layer such that the passivation layer is exposed at the exposed regions.

37. The solar cell structure of claim 34, wherein the substrate comprises a carrier selective transport layer and wherein the portions of the dielectric layer are removed to form the one or more exposed regions in the dielectric layer such that the carrier selective transport layer is exposed at the exposed regions.

38. The solar cell structure of claim 34, wherein the substrate comprises at least one first doped region of a first doping concentration and dielectric or passivation layer profile and at least one second doped region located at a surface portion of the semiconductor material and in electrical contact with the first region, and wherein the at least one second region has a dielectric or passivation layer profile different to that of the first region.

39. The solar cell structure of claim 38, wherein the at least one second region extends along, and within the bounds of, a notional band defined by spaced-apart side boundary lines that are substantially parallel with a longitudinal axis of the conductive portion, and wherein a width of the notional band is greater than a width of the conductive portion.

40. The solar cell structure of claim 39, wherein the width of the notional band is less than approximately 150 μm and wherein the width of the conductive portion is: less than 2 mm, or less than 1 mm, or less than 500 μm, or less than 100 μm, or less than 50 μm, or between 20 μm and 40 μm, or approximately 30 μm.

41. (canceled)

42. The solar cell structure of claim 38, wherein each second region is continuous.

43. The solar cell structure of claim 38, wherein the at least one second region traverses the conductive portion between 2 and 20 times per millimetre, or between 5 and 10 times per millimetre, measured along a longitudinal axis of the conductive portion.

44. (canceled)

45. The solar cell structure of claim 38, wherein a total surface area of the conductive portion overlapping the at least one second region is less than 2% of a total area of the surface of the solar cell structure on which the conductive portion is located.

46. The solar cell structure of claim 38, wherein a width of the at least one second region is: between 10 μm and 50 μm; or approximately 20 μm.

47. The solar cell structure of claim 38, wherein a form of the at least one second region approximates a wave shape.

48. The solar cell structure of claim 38, wherein the conductive portion comprises a metallic material and is applied by screen printing; and/or
the conductive portion is in the form of a distinct metal finger and the at least one second region only traverses the metal finger along a length of the finger.

49.-50. (canceled)

51. The solar cell structure of claim 38, wherein the dielectric layer comprises at least one of: polysilicon; conductive oxide; conductive oxide that is less than 200 nm thick.
